(19) United States
(12) Patent Application Publication
(10) Pub. No.: US 2025/0389023 A1
(43) Pub. Date: Dec. 25, 2025

(54) REACTOR SYSTEM COMPRISING A TUNING CIRCUIT

(71) Applicant: ASM IP Holding B.V., Almere (NL)

(72) Inventors: Ryu Nakano, Sagamihara-shi (JP); Fumitaka Shoji, Kawasaki-shi (JP)

(21) Appl. No.: 19/313,042

(22) Filed: Aug. 28, 2025

Related U.S. Application Data
(63) Continuation of application No. 17/307,643, filed on May 4, 2021, now Pat. No. 12,442,082.
(60) Provisional application No. 63/021,592, filed on May 7, 2020.

(51) Int. Cl. C23C 16/458; H01L 21/67; H01L 21/683

(52) U.S. Cl. CPC C23C 16/4586; H01L 21/6833; H01L 21/67069

(57) ABSTRACT

A susceptor assembly for a reactor system may comprise a susceptor body defined by a susceptor outer edge, the susceptor body comprising a susceptor outer portion and a susceptor inner portion, wherein the susceptor outer portion is proximate the susceptor outer edge, and the susceptor inner portion is at least partially enclosed within the susceptor outer portion; a first tuning circuit comprising an edge electrode and a first resonance circuit coupled to the edge electrode, wherein the edge electrode is coupled to the susceptor body; a second tuning circuit comprising a center electrode and a second resonance circuit coupled to the center electrode, wherein the center electrode is coupled to the susceptor body; wherein the edge electrode is disposed more proximate the susceptor outer edge than the center electrode.

### CROSS-REFERENCE TO RELATED APPLICATIONS

This application is a continuation of, and claims priority to, U.S. patent application Ser. No. 17/307,643 filed May 4, 2021 titled REACTOR SYSTEM COMPRISING A TUNING CIRCUIT; which claims the benefit of and priority to U.S. Provisional Application No. 63/021,592, filed on May 7, 2020 in the United States Patent and Trademark Office, the disclosures of which are incorporated herein in their entirety by reference.

### FIELD OF THE DISCLOSURE

The present disclosure relates generally to a semiconductor processing or reactor system, and particularly a semiconductor reactor system, and components comprised therein, which facilitates more uniform process across a surface within the reactor, for example, on a substrate.

### BACKGROUND OF THE DISCLOSURE

Reaction chambers may be used for processing a substrate therein (e.g., depositing various material layers onto semiconductor substrates). A substrate may be placed on a susceptor inside a reaction chamber. Both the substrate and the susceptor may be heated to a desired substrate temperature set point. In an example substrate treatment process, one or more reactant gases may be passed over a heated substrate, causing the deposition of a thin film of material on the substrate surface. Throughout subsequent deposition, doping, lithography, etch, and other processes, these layers may be made into integrated circuits.

The deposition or other processing on the surface of a substrate may have a desired pattern. For example, it may be desired to have a layer(s) of deposited material on a substrate with a uniform thickness across the substrate surface. That is, an even deposition of material may be desirable. However, in some instances, the material deposition at or proximate one portion of a substrate (e.g., an edge of a substrate) may be different than the deposition on another area of the substrate (e.g., an area more proximate the center of the substrate). Accordingly, systems and methods are therefore desirable that allow the ability to adjust the amount of processing on a substrate in certain areas of the substrate (e.g., for facilitating more even and/or uniform deposition on a surface of a substrate).

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, a reactor system is provided. The reactor system disclosed herein may allow adjustable material deposition on, and/or processing of, a substrate, for example, to achieve more uniform material deposition on, and/or processing of, the substrate.

In various embodiments, a reactor system may comprise a susceptor assembly comprising a susceptor body defined by a susceptor outer edge, the susceptor body comprising a susceptor outer portion and a susceptor inner portion, wherein the susceptor outer portion is proximate the susceptor outer edge, and the susceptor inner portion is at least partially enclosed within the susceptor outer portion; a first tuning circuit comprising an edge electrode and a first resonance circuit coupled to the edge electrode, wherein the edge electrode is coupled to the susceptor body; and a second tuning circuit comprising a center electrode and a second resonance circuit coupled to the center electrode, wherein the center electrode is coupled to the susceptor body. The edge electrode may be disposed more proximate the susceptor outer edge than the center electrode. In various embodiments, the first resonance circuit may comprise a first capacitor and/or a first inductor. In various embodiments, the first capacitator may have a first adjustable capacitance, and/or the first inductor may have a first adjustable inductance. In various embodiments, the first resonance circuit may further comprise a first additional capacitor. In various embodiments, the second resonance circuit may comprise a second capacitor and/or a second inductor. In various embodiments, the second capacitator may have a second adjustable capacitance, and/or the second inductor may have a second adjustable inductance. In various embodiments, the second resonance circuit may further comprise a second additional capacitor.

In various embodiments, the edge electrode may span along at least a portion of the susceptor outer portion. In various embodiments, the susceptor assembly may further comprise a second edge electrode spanning along a second portion of the susceptor outer portion. The second portion of the susceptor outer portion may be different than the portion of the susceptor outer portion along which the edge electrode spans. In various embodiments, the second edge electrode may be comprised in the first tuning circuit and coupled to the first resonance circuit, and/or the second edge electrode may be comprised in a third tuning circuit and coupled to a third resonance circuit of the third tuning circuit. In various embodiments, the first tuning circuit may further comprise a first wire coupled to and between the edge electrode and the first resonance circuit, and/or the second tuning circuit may further comprise a second wire coupled to and between the center electrode and the second resonance circuit. In various embodiments, an outer edge of the edge electrode may at least partially define a first shape, wherein an edge electrode void may be disposed within the first shape and at least partially enclosed by the edge electrode.

In various embodiments, the center electrode may be defined by a center electrode outer edge and may be disposed in, and may span at least a portion of, the susceptor inner portion. The center electrode may be disposed at least partially within the edge electrode void. In various embodiments, the susceptor assembly may further comprise a second center electrode disposed at least partially within the edge electrode void and spanning a second portion of the susceptor inner portion, wherein the second portion of the susceptor inner portion may be different than the portion of the susceptor inner portion which the center electrode spans. In various embodiments, the second center electrode may be comprised in the second tuning circuit and coupled to the second resonance circuit, and/or the second center electrode may be comprised in a third tuning circuit and coupled to a third resonance circuit of the third tuning circuit. In various embodiments, the center electrode outer edge may at least partially define a second shape. In various embodiments, the first shape and the second shape may be concentric.

In various embodiments, a susceptor for a reactor system may comprise a susceptor body defined by a susceptor outer edge, the susceptor body comprising a susceptor outer portion and a susceptor inner portion, wherein the susceptor outer portion may be proximate the susceptor outer edge, and the susceptor inner portion may be within the susceptor outer portion; an edge electrode coupled to the susceptor body; and/or a center electrode coupled to the susceptor body. The edge electrode may be disposed more proximate the susceptor outer edge than the center electrode. In various embodiments, a first impedance of the edge electrode may be adjustable, and/or a second impedance of the center electrode may be adjustable. In various embodiments, the edge electrode may span along at least a portion of the susceptor outer portion, defining at least a portion of an edge electrode shape, wherein the edge electrode at least partially encloses an edge electrode void. The center electrode may be defined by a center electrode outer edge, wherein the center electrode may be disposed in the susceptor inner portion and at least partially in the edge electrode void. In various embodiments, the edge electrode shape may comprise a first circular shape, and/or the center electrode outer edge may comprise a second circular shape.

In various embodiments, a method may comprise adjusting an impedance of at least one of a first resonance circuit or a second resonance circuit; adjusting a first electric field proximate a first electrode coupled to the first resonance circuit in response to adjusting the impedance of the first resonance circuit, wherein the first electrode is coupled to a susceptor; and/or adjusting a second electric field proximate a second electrode coupled to the second resonance circuit in response to the adjusting the impedance of the second resonance circuit, wherein the second electrode may be coupled to the susceptor at a different portion than the first electrode. In various embodiments, the first electrode may span along at least a portion of an outer portion of the susceptor, the susceptor outer portion being proximate a susceptor outer edge. The second electrode may be disposed at an inner portion of the susceptor, wherein the susceptor inner portion may be within the susceptor outer portion.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1 is a schematic diagram of an exemplary reactor system, in accordance with various embodiments;

FIG. 2A is a schematic diagram of an exemplary reaction chamber with a susceptor disposed in a lower position, in accordance with various embodiments;

FIG. 2B is a schematic diagram of an exemplary reaction chamber with a susceptor disposed in a raised position, in accordance with various embodiments;

FIG. 3 illustrates a cross-sectional view of a susceptor comprising electrodes, in accordance with various embodiments;

FIG. 4 illustrates a top view of electrodes configured to be coupled to and/or disposed in a susceptor, in accordance with various embodiments;

FIG. 5 illustrates a method for processing a substrate in a reactor system, in accordance with various embodiments; and

FIGS. 6A-6D depict plots illustrating the electric field above a substrate on a susceptor, the susceptor comprising an edge electrode and a center electrode, with varying impedance levels of the edge electrode and the center electrode, in accordance with various embodiments.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As used herein, the term “substrate” may refer to any underlying material or materials that may be used, or upon which, a device, a circuit, or a film may be formed.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which react and/or decompose on a substrate surface to produce a desired deposition.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

As used herein, the term “contaminant” may refer to any unwanted material disposed within the reaction chamber that may affect the purity of a substrate disposed in the reaction chamber. The term “contaminant” may refer to, but is not limited to, unwanted deposits, metal and non-metal particles, impurities, and waste products, disposed within the reaction chamber.

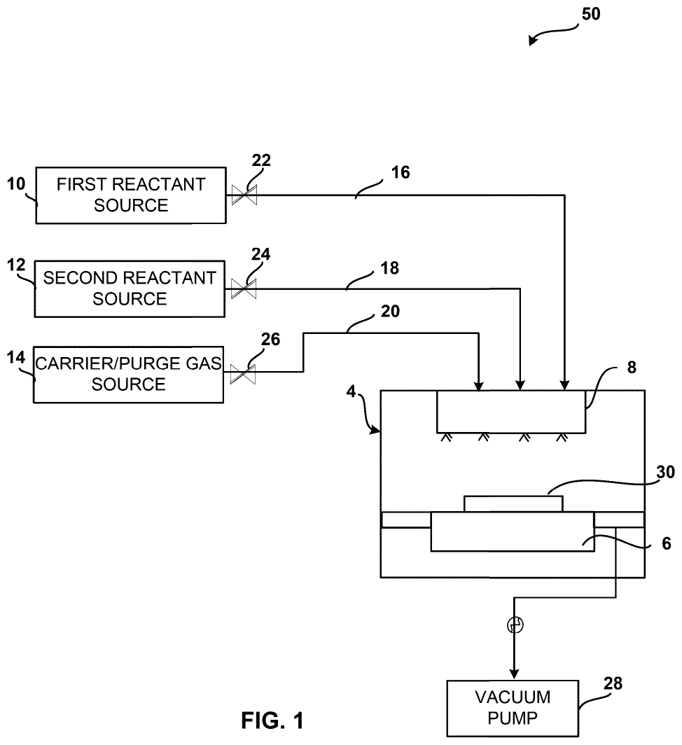

Reactor systems used for ALD, CVD, and/or the like, may be used for a variety of applications, including depositing and etching materials on a substrate surface. In various embodiments, with reference to FIG. 1, a reactor system 50 may comprise a reaction chamber 4, a susceptor 6 to hold a substrate 30 during processing, a fluid distribution system 8 (e.g., a showerhead) to distribute one or more reactants to a surface of substrate 30, one or more reactant sources 10, 12, and/or a carrier and/or purge gas source 14, fluidly coupled to reaction chamber 4 via lines 16-20 and valves or controllers 22-26. System 50 may also comprise a vacuum source 28 fluidly coupled to the reaction chamber 4.

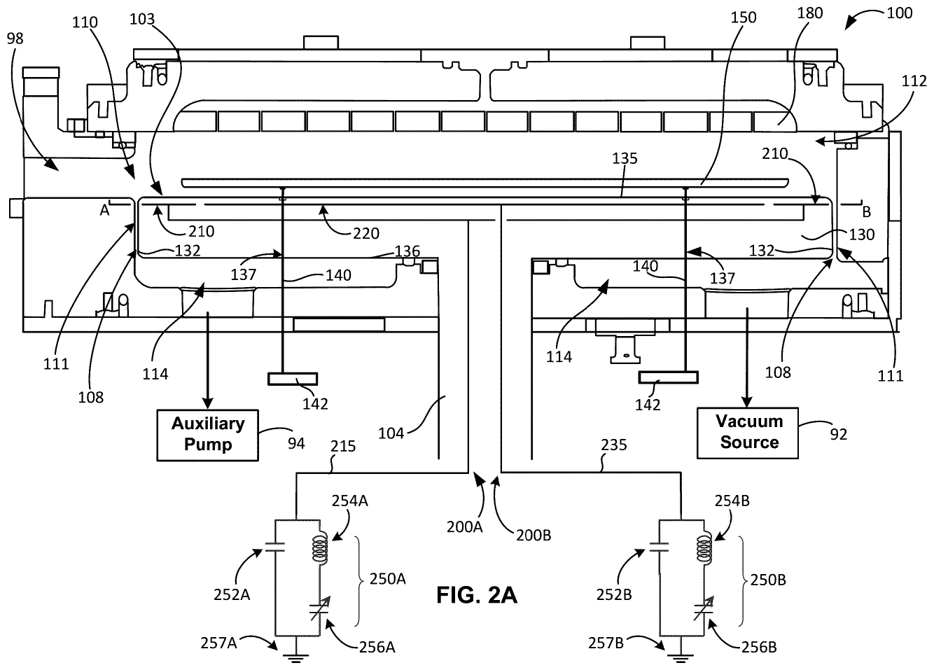

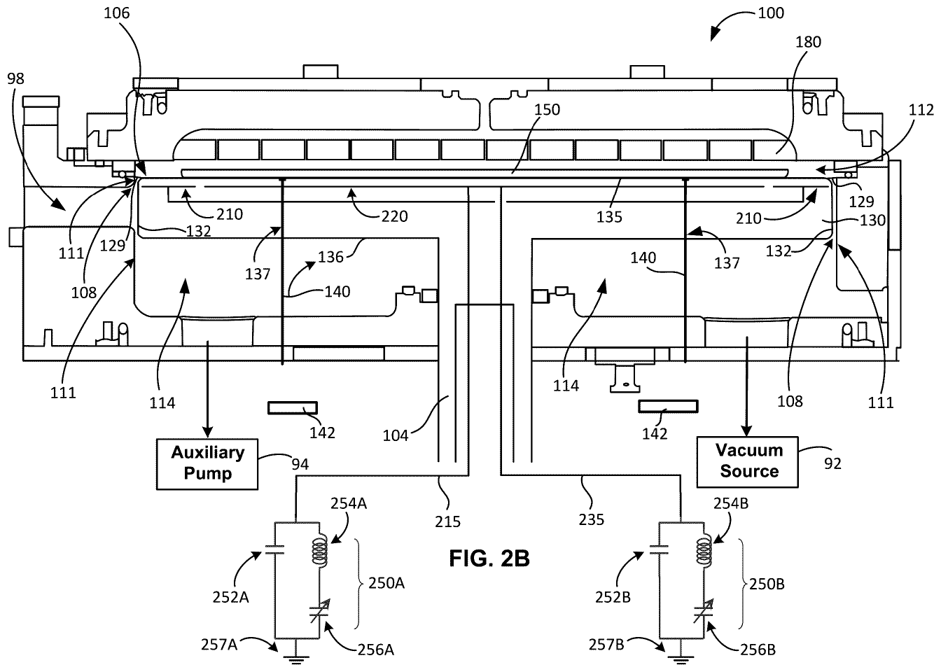

Turning to FIGS. 2A and 2B, the embodiments of the disclosure may include reactor systems and methods that may be utilized for processing a substrate within a reactor system 100. In various embodiments, a reactor system 100 may comprise a reaction chamber 110 for processing substrates. In various embodiments, reaction chamber 110 may comprise a reaction space 112 (i.e., an upper chamber), which may be configured for processing one or more substrates, and/or a lower chamber space 114 (i.e., a lower chamber). Lower chamber space 114 may be configured for the loading and unloading of substrates from the reaction chamber, and/or for providing a pressure differential between lower chamber space 114 and reaction space 112.

In various embodiments, reaction space 112 and lower chamber space 114 may be separated by a susceptor 130 disposed in reaction chamber 110. In various embodiments, reaction space 112 and lower chamber space 114 may be substantially fluidly separate or isolated from one another. For example, a susceptor 130 may fluidly separate reaction space 112 and lower chamber space 114 by creating at least a partial seal (i.e., at least restricting fluid flow) between susceptor 130 and a chamber sidewall 111 of reaction chamber 110 disposed proximate a susceptor outer edge 132 of susceptor 130. That is, space 108 between susceptor 130 and chamber sidewall 111 may be minimized or eliminated such that there is little or no fluid movement between susceptor 130 and chamber sidewall 111.

In various embodiments, to prevent or reduce fluid flow between susceptor 130 and chamber sidewall 111, one or more sealing members (e.g., sealing members 129) may extend from susceptor 130 (e.g., from susceptor outer edge 132) and/or from chamber sidewall 111 of reaction chamber 110 to the other, creating at least a partial seal (i.e., restricting or preventing fluid flow) between susceptor 130 and chamber sidewall 111. The at least partial sealing of reaction space 112 from lower chamber space 114 may be desirable to prevent or reduce precursor gases, and/or other fluids, utilized in the processing of a substrate 150, from entering and/or contacting lower chamber space 114 of reaction chamber 110. For example, the precursor gases utilized for processing substrates in the reaction space may comprise corrosive deposition precursors which may contact lower chamber space 114 producing unwanted deposits/contaminants/particles, which may in turn be reintroduced into reaction space 112, thereby providing a source of contamination to a substrate disposed in the reaction space.

In various embodiments, although sealing members 129 extending between susceptor 130 and chamber sidewall 111 of reaction chamber 110, and/or the at least partial seal formed by direct contact between susceptor 130 and chamber sidewall 111 of reaction chamber 110, may restrict or substantially prevent fluid communication between reaction space 112 and lower chamber space 114 through space 108, it may still be possible for a small volume of precursor gases to enter lower chamber space 114 by diffusion, which may result in possible corrosion, unwanted deposition and contaminants, in the lower chamber of the reaction chamber of the reactor system.

In various embodiments, susceptor 130 may comprise one or more pin holes 137. Each pin hole 137 may span through susceptor 130 from a top surface of susceptor 130 (e.g., a substrate support surface 135 on which substrate 150 may be disposed for processing) to a bottom surface 136 of susceptor 130. The susceptor top surface (e.g., substrate support surface 135) may be the surface of susceptor 130 proximate reaction space 112 of reaction chamber 110. Susceptor bottom surface 136 may be the surface of susceptor 130 proximate lower chamber space 114 of reaction chamber 110. With no lift pin disposed in a pin hole 137, reaction space 112 and lower chamber space 114 may be in fluid communication with one another through pin hole 137. That is, pinhole(s) 137 may be in fluid communication with reaction space 112 and lower chamber space 114.

A lift pin 140 (or other like object) may be disposed in each pin hole 137. Each lift pin may comprise a lift pin body, which is configured to span at least a portion of a pin hole 137 when disposed in pin hole 137. The lift pin body may comprise a cross-sectional shape that is complementary to a cross-sectional shape of pin hole 137. In various embodiments, a pin top surface of each lift pin may be configured to contact substrate 150 to move substrate 150 relative to susceptor 130. For example, lift pin(s) 140 may cause substrate 150 to move up or down relative to susceptor 130 (i.e., increase or decrease the space between substrate 150 and susceptor 130). Disposing the substrate on lift pins may facilitate loading or unloading of the substrate from the reaction chamber, for example, through an opening (e.g., opening 98) in the chamber sidewall.

As discussed, substrate 150 and susceptor 130 may be movable relative to one another. For example, in various embodiments, one or more lift pins 140 may be configured to allow substrate 150 to separate from susceptor 130, and to allow substrate 150 to be placed in contact with (i.e., to be supported by) susceptor 130. In various embodiments, susceptor 130 may move, for example via a susceptor elevator 104, up or down such that susceptor 130 moves relative to substrate 150. In various embodiments, lift pins 140 may move up or down, for example via lift pin elevators/platforms 142 such that substrate 150 moves relative to 130 susceptor. In various embodiments, susceptor 130 and/or lift pins 140 may be stationary while the other is moving. In various embodiments, susceptor 130 and/or lift pins 140 may be configured to move relative to the other.

In various embodiments, the reactor system may comprise a susceptor (e.g., susceptor 130). The substrate (e.g., substrate 150) may be disposed directly on top of the susceptor (e.g., on substrate support surface 135 of susceptor 130) for processing. In various embodiments, a top surface of the susceptor may be disposed on the same plane as substrate support surface 135. In various embodiments, the substrate support surface may be recessed into the susceptor such that there is a recess in the top surface of the susceptor. The recess comprising substrate support surface 135 may comprise a height such that at least a portion of the height of substrate 150 is disposed in the recess. The recess may comprise a height such that, when the substrate is disposed on the substrate support surface and within the recess, the top surface of the substrate is flush with the top surface of the susceptor.

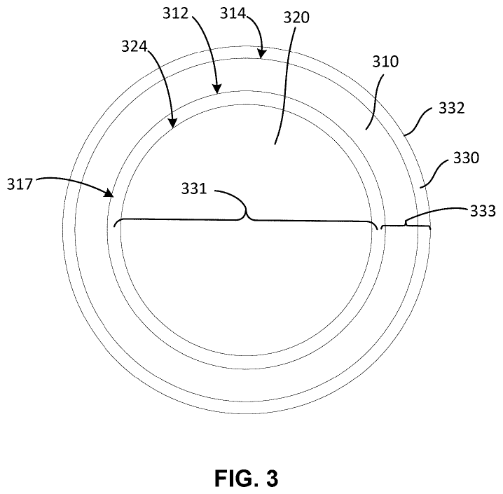

In various embodiments, once substrate 150 is disposed on lift pins 140, susceptor 130 may move from loading position 103 to processing position 106, receiving substrate 150 during such movement. In such embodiments, the pin top end and/or the pin heads or top surfaces of lift pins 140 may be received by pin holes 137 (pin hole 337 in FIG. 3), and therefore, substrate 150 may directly contact susceptor 130. In various embodiments, once substrate 150 is disposed on lift pins 140, lift pins 140 may move downward into susceptor 130, such that substrate 150 is received by susceptor 130 (i.e., such that substrate 150 rests on substrate support surface 135). In response, the pin top ends (e.g., pin top ends 310 of lift pins 300) may be flush with and/or below substrate support surface 135. Substrate 150 may be subsequently processed within the reaction chamber.

During processing of a substrate on a susceptor, an electric field may form at or around one or more portions of the susceptor. Without being bound by theory, differences in the electric field(s) proximate different portions of the susceptor may cause the processing of the substrate at such portions of the susceptor to differ. For example, during a deposition process (e.g., ALD), the difference in the electric field proximate an edge portion of the susceptor versus the electric field proximate a center portion of the susceptor may cause different material deposition on the substrate proximate the edge portion versus the center portion of the susceptor.

In various embodiments, a reactor may comprise one or more tuning circuits to allow adjustment of the electric field at or around one or more portions of the susceptor in the reactor. A tuning circuit may be coupled to the susceptor. In various embodiments, a tuning circuit may comprise an electrode and a resonance circuit coupled to the electrode. The electrode of a tuning circuit may be coupled to and/or disposed within the susceptor of the reactor. The electrode may be electrically coupled to the resonance circuit, for example by a wire (e.g., a metallic wire), such that current may flow from the electrode to the resonance circuit. The resonance circuit may be grounded.

In various embodiments, a resonance circuit may comprise at least one capacitor and/or at least one inductor. A resonance circuit may comprise a capacitor with a fixed capacitance and/or a capacitor with a variable capacitance. Similarly, a resonance circuit may comprise an inductor with a fixed inductance and/or an inductor with a variable inductance. Each resonance circuit coupled to the susceptor may comprise an impedance level resulting from the capacitor(s) and inductor(s). The impedance level of a resonance circuit may be adjustable, for example, through adjustment of the capacitance of the capacitor and/or the inductance of the inductor.

In various embodiments, the electrode of a tuning circuit may be coupled to, or comprised in, a susceptor such that the electrode occupies, spans, and/or is proximate to a certain portion of the susceptor (e.g., a certain portion of the substrate support surface of the susceptor). A reactor may comprise multiple electrodes coupled to, or comprised in, a susceptor, wherein the electrodes may span, or be disposed at or proximate to, different portions of the susceptor and/or different portions of the substrate support surface of the susceptor. The electrodes may span along the same plane (e.g., a plane proximate, adjacent, parallel, and/or abutting the substrate support surface of the substrate). An electrode may be disposed within a susceptor such that the plane along which the electrode spans is approximately 0.1 centimeter (cm) away from the substrate support surface of the susceptor within the susceptor body (wherein “approximately in this context means plus or minus 0.05 cm).

A first electrode of a first tuning circuit may be at or proximate an outer (i.e., edge) portion of the susceptor or substrate support surface of the susceptor, and a second electrode of a second tuning circuit may be at or proximate an inner (i.e., center) portion of the susceptor or susceptor substrate support surface. As another example, the susceptor or susceptor substrate support surface may divided up into quadrants or portions, and an electrode of a respective tuning circuit may be disposed at or proximate, or may span along, each quadrant or portion of the susceptor or susceptor substrate support surface. Each electrode may be coupled to a respective resonance circuit.

With reference to FIGS. 2A and 2B, reactor system 100 may comprise a first tuning circuit 200A and a second tuning circuit 200B. First tuning circuit 200A may comprise a first electrode (an edge electrode 210) coupled to a first resonance circuit 250A. Edge electrode 210 and first resonance circuit 250A may be electrically coupled, for example, by wire 215 such that current may flow between edge electrode 210 and first resonance circuit 250A. Edge electrode 210 may be coupled to and/or comprised within susceptor 130 (i.e., within a susceptor body of susceptor 130). In various embodiments, edge electrode may be at least partially enclosed within the body of susceptor 130, and may be proximate or adjacent to, abutting, or spanning along the substrate support surface (substrate support surface 135) of the susceptor. An edge electrode may span along at least a portion of the of an outer portion of the susceptor. For example, edge electrode 210 may be disposed at or proximate, and span at least partially along, an outer portion of susceptor 130. As another example, with additional reference to FIG. 3, edge electrode 310 (an example of edge electrode 210) may be disposed in outer portion 333 of susceptor 330. The outer portion of a susceptor may be the portion more proximate an outer edge of the susceptor (e.g., more proximate outer edge 132 of susceptor 130, or outer edge 332 of susceptor 330) than an inner, or center, portion of the susceptor. For example, an outer portion of a susceptor may be a portion spanning along or proximate to the outer edge of the susceptor, and may be about, for example, a sixth, a fifth, a quarter, a third, a half, or greater than half of the distance from the outer edge of the susceptor toward the center of the susceptor (i.e., on a circular susceptor, along the radius of the susceptor starting at the outer edge spanning toward the center of the susceptor).

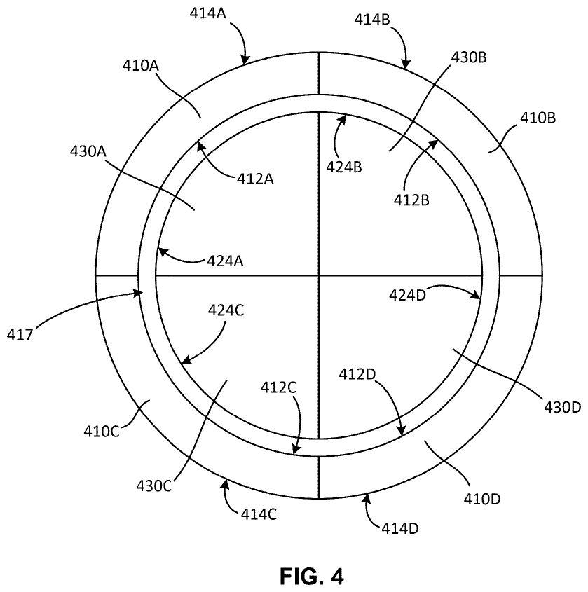

The edge electrode (e.g., edge electrode 210 or 310) may be defined by an outer edge (e.g., outer edge 314 of edge electrode 310). The outer edge of the edge electrode may at least partially define a first shape. For example, outer edge 314 of edge electrode 310 defines a circle. As another example, with reference to FIG. 4, the outer edge of each of the four edge electrodes 410A-410D (outer edges 414A-414D, respectively) partially defines a circle. The shape at least partially defined by the outer edge of the edge electrode may be any suitable shape (e.g., a circle, square, rectangle, oval, hexagon, and/or the like).

In various embodiments, an inner boundary of the edge electrode may be defined by an inner edge of the edge electrode (e.g., inner edge 312 of edge electrode 310). The edge electrode body may span between the inner edge and the outer edge. The inner edge of the edge electrode may at least partially define a second shape. For example, inner edge 312 of edge electrode 310 defines a circle. The second shape at least partially defined by the inner edge of the edge electrode may define an edge electrode void. The edge electrode void may be at least partially enclosed by the edge electrode and/or the inner edge of the edge electrode. The edge electrode void may be disposed within the first shape defined by the outer edge of the edge electrode and/or within the second shape defined by the inner edge of the edge electrode. For example, inner edge 312 of edge electrode 310 may define edge electrode void 317, which is enclosed by edge electrode 310. Similarly, edge electrode void 317 is disposed within the first shape defined by outer edge 314 of edge electrode 310 and/or within the second shape defined by inner edge 312 of edge electrode 310. As another example, with reference to FIG. 4, the inner edge of each of the four edge electrodes 410A-410D (inner edges 412A-412D, respectively) partially defines a shape (a circle). The edge electrode void (e.g., edge electrode void 417) may be at least partially enclosed by each of edge electrodes 410A-410D and/or each of the inner edges 412A-412D of each edge electrode 410A-410D. Edge electrode void 417 may be disposed within the shape partially defined by outer edges 414A-414D of edge electrodes 410A-410D and/or within the shape defined by inner edge 412A-412D of edge electrodes 410A-410D. The shape at least partially defined by the inner edge of the edge electrode may be any suitable shape (e.g., a circle, square, rectangle, oval, hexagon, and/or the like).

In various embodiments, the edge electrode body may span any suitable length between the outer edge (e.g., outer edge 314) and the inner edge (e.g., inner edge 312). The edge electrode body may span a length between the outer edge and inner edge of about, for example, 2 centimeters (cm), 4 cm, 7 cm, or 10 cm (wherein “about” in this context means plus or minus 1 cm). The length between the outer edge and inner edge of the edge electrode may be constant (as shown by edge electrode 310) or variable.

In various embodiments, the outer edge of the edge electrode may be radially outward (relative a center point of the shape defined by the edge electrode or the susceptor shape) of the outer edge of the susceptor (or the outer edge of the substrate support surface of the susceptor) such that the outer edge of the edge electrode protrudes further than the shape defined by the susceptor outer edge (or the shape defined by the substrate support surface of the susceptor). In various embodiments, the outer edge of the edge electrode may be flush with the outer edge of the susceptor (or the substrate support surface of the susceptor). In various embodiments, the outer edge (e.g., outer edge 314) of the edge electrode (e.g., edge electrode 310) may be radially inward of the outer edge of the susceptor (susceptor outer edge 332), or the outer edge of the substrate support surface of the susceptor, such that the susceptor outer edge, or the outer edge of the substrate support surface of the susceptor, is disposed radially further outward than the outer edge of the edge electrode.

In various embodiments, any suitable number of electrodes may be disposed in or proximate to, or coupled to, a certain portion of the susceptor. That is, one electrode may be coupled to and/or disposed in any suitable portion of the susceptor, spanning or occupying a respective portion of the susceptor or the susceptor substrate support surface. Another electrode may be similarly coupled to and/or disposed in another suitable portion of the susceptor, spanning or occupying another respective portion of the susceptor or the susceptor substrate support surface, which is a different portion occupied by the first electrode. In various embodiments, such electrodes may span along the same plane. For example, the outer portion 333 of susceptor 330 may be divided into halves, thirds, fourths, fifths, sixths, or the like, with an edge electrode being disposed in or proximate to, or coupled to, each section of the susceptor outer portion. For example, as depicted in FIG. 4, the outer portion of the susceptor may be divided into fourths, with one of edge electrodes 410A-410D disposed in or proximate to, or coupled to, each fourth of the susceptor. The edge electrodes occupying the outer portion of a susceptor, or the substrate support surface of the susceptor, may be equidistant from one another disposed about a center point. In various embodiments, the edge electrodes may be abutting one another or they may be spaced apart. In various embodiments, the edge electrodes (e.g., edge electrodes 410A-410C) may be spaced apart from each other by any suitable distance, for example, about 0.1 cm, 0.5 cm, 1.0 cm, or 3.0 cm (wherein “about” in this context means plus or minus 0.1 cm). Split electrodes disposed in the outer portion of a susceptor (e.g., edge electrodes 410A-410D) may comprise any suitable arrangement, such as a column, row, and/or grid pattern.

In various embodiments, second tuning circuit 200B may comprise a second electrode (a center electrode 220) coupled to a second resonance circuit 250B. The second electrode of second tuning circuit 200B may be disposed in or proximate to a different portion of susceptor 130 and/or susceptor support surface 135 than the first electrode. Center electrode 220 and second resonance circuit 250B may be electrically coupled, for example, by wire 235 such that current may flow between center electrode 220 and second resonance circuit 250B. Center electrode 220 may be coupled to and/or comprised within susceptor 130 (i.e., within a susceptor body of susceptor 130). In various embodiments, a center electrode may be at least partially enclosed within the body of the susceptor, and may be proximate or adjacent to, abutting, or spanning parallel to the substrate support surface (substrate support surface 135) of the susceptor. The center electrode may span along the same plane as the edge electrode.

In various embodiments, a center electrode may span along at least a portion of an inner portion of the susceptor. For example, center electrode 220 may be disposed in or proximate an inner portion of susceptor 130. As another example, with additional reference to FIG. 3, center electrode 320 (an example of center electrode 220) may be disposed in inner portion 331 of susceptor 330. The inner portion of a susceptor may the portion more proximate a center of the susceptor than an outer portion of the susceptor. For example, an outer portion of a susceptor may be a portion spanning within, or at least partially enclosed by, an outer portion (e.g., outer portion 333) of the susceptor, as discussed herein, and may be about, for example, a half, two-thirds, three-fourths, four fifths, five-sixths, or a greater length from the center of the susceptor to the outer edge of the susceptor (e.g., on a circular susceptor, such a distance would be a radial distance from the center of the susceptor).

The center electrode (e.g., center electrode 220 or 320) may be defined by an outer edge (e.g., outer edge 334 of center electrode 320). The outer edge of the center electrode may at least partially define a first shape. For example, outer edge 324 of center electrode 320 defines a circle. As another example, with reference to FIG. 4, the outer edge of each of the four center electrodes 420A-420D (outer edges 424A-424D, respectively) partially defines a circle. The shape at least partially defined by the outer edge of the center electrode may be any suitable shape (e.g., a circle, square, rectangle, oval, hexagon, and/or the like).

Similar to the edge electrodes discussed herein, in various embodiments, any suitable number of electrodes may be disposed in or proximate to, or coupled to, a certain portion of the susceptor. For example, the inner portion 331 of susceptor 330 may be divided into halves, thirds, fourths, fifths, sixths, or the like, with a center electrode being disposed in or proximate to, or coupled to, each section of the susceptor outer portion. For example, as depicted in FIG. 4, the inner portion of the susceptor may be divided into fourths, with one of center electrodes 420A-420D disposed in or proximate to, coupled to, or spanning along each fourth of the susceptor. The center electrodes occupying the inner portion of a susceptor, or the substrate support surface of the susceptor, may be equidistant from one another disposed about a center point. The center electrodes may be abutting one another or they may be spaced apart. In various embodiments, the center electrodes (e.g., center electrodes 420A-420C) may be spaced apart from each other by any suitable distance, for example, about 0.1 cm, 0.5 cm, 1.0 cm, or 3.0 cm (wherein “about” in this context means plus or minus 0.1 cm). Split electrodes disposed in the inner portion of a susceptor (e.g., center electrodes 420A-420D) may comprise any suitable arrangement, such as a column, row, and/or grid pattern.

In various embodiments, the center electrode (e.g., center electrode 220 or 320) may be disposed at least partially within the shape at least partially defined by the outer edge or inner edge of an edge electrode (e.g., edge electrode 210 or 310). In various embodiments, the center electrode (e.g., center electrode 220 or 320) may be disposed at least partially within an edge electrode void (e.g., edge electrode void 317). There may be a space between the center electrode and the edge electrode. For example, with reference to FIG. 3, the inner edge 312 of edge electrode 310 may be spaced apart from the outer edge 324 of center electrode 320. In various embodiments, the edge electrode may be spaced apart from the center electrode by any suitable distance, for example, about 0.1 cm, 0.5 cm, 1.0 cm, or 3.0 cm (wherein “about” in this context means plus or minus 0.1 cm). In various embodiments, the center electrode and the edge electrode may abut one another.

The electrodes disposed in or coupled to a susceptor may be disposed in any suitable configuration or arrangement. In various embodiments, the shape defined by the inner or outer edge of the edge electrode may be concentric with the shape defined by the outer edge of the center electrode. For example, as illustrated in FIG. 3, the shape defined by outer edge 314 and inner edge 312 of edge electrode 310 may be concentric with the shape defined by outer edge 324 of center electrode 320. As is the case with edge electrode 310 and center electrode 320, the edge electrode and the center electrode may be concentric. In various embodiments, the center electrode may comprise a void therethrough, similar to an edge electrode void. The center electrode void may be disposed at any suitable location through center electrode. In various embodiments, there may be more than one electrodes disposed radially outward of the center electrode. For example, there may be three or more electrodes disposed radially inward of one another. As a further example, the three or more electrodes may define concentric shapes. In various embodiments, electrodes coupled to and/or disposed in a susceptor may comprise other arrangements such as rows, columns, a grid, and/or random arrangements of electrodes in one or more portions of the susceptor.

In various embodiments, each tuning circuit in a reactor may comprise a resonance circuit. The resonance circuit may be coupled to one or more electrodes. For example, resonance circuit 250A may be coupled to edge electrode 210 (or edge electrode 310). Similarly, a resonance circuit may be coupled to one or more of edge electrodes 410A-410B, or each of edge electrodes 410A-410B may be coupled to one or more resonance circuits. As another example, resonance circuit 250B may be coupled to center electrode 220 (or center electrode 320). Similarly, a resonance circuit may be coupled to one or more of center electrodes 420A-420B, or each of center electrodes 420A-420B may be coupled to one or more resonance circuits. A resonance circuit may be coupled to an electrode in the tuning circuit by a wire (e.g., wire 215 or 235), which may comprise a metal or metal alloy. In various embodiments, the wire coupling a resonance circuit to an electrode may comprise a dielectric material along at least a portion of the wire. For example, a wire coupling a resonance circuit to an electrode may comprise a dielectric material disposed along a portion of the wire proximate and/or adjacent to the resonance circuit.

Each resonance circuit in a tuning circuit may comprise an inductor and/or a capacitor. The inductor may be any suitable inductor. The capacitor may be any suitable capacitor. In various embodiments, an inductor may comprise any suitable level of inductance, for example, from 1 nanohenry (nH) to 1 microhenry (μH). In various embodiments, a capacitor may comprise any suitable level of capacitance, for example, from 0.1 picofarad (pF) to 1 microfarad (μF).

In various embodiments, a resonance circuit in a tuning circuit may comprise one or more inductors and/or one or more capacitors. The inductor(s) and/or capacitor(s) may be disposed in any suitable arrangement. For example, the inductor(s) and/or capacitor(s) may be in series or in parallel with any other inductor(s) and/or capacitor(s). As depicted in FIGS. 2A and 2B, resonance circuits 250A and 250B each comprise an inductor (e.g., inductor 254A in resonance circuit 250A, and inductor 254B in resonance circuit 250B) and a capacitor (e.g., capacitor 252A in resonance circuit 250A, and capacitor 252B in resonance circuit 250B). Additionally, resonance circuits 250A and 250B may each comprise an additional capacitator (e.g., additional capacitor 256A in resonance circuit 250A, and additional capacitor 256B in resonance circuit 250B). In various embodiments, at least one inductor and/or capacitor may be adjustable, thereby allowing the impedance of the resonance circuit to be adjustable. As depicted in FIGS. 2A and 2B, additional capacitor 256A in resonance circuit 250A, and additional capacitor 256B in resonance circuit 250B, are adjustable.

The resonance circuit of a tuning circuit may be disposed in any suitable position of the reactor or reactor system. For example, the resonance circuit (e.g., resonance circuits 250A and 250B in FIGS. 2A and 2B) may be external to the reactor and reaction chamber (e.g., reaction chamber 110). In various embodiments, a resonance circuit may be comprised in a reactor and/or reaction chamber. Wires (e.g., wires 215 and 235) may connect a resonance circuit to a respective electrode comprised in the reaction chamber and/or susceptor. In various embodiments, a resonance circuit may be coupled to ground, such that the resonance circuit is coupled between an electrode and ground. For example, as depicted in FIGS. 2A and 2B, resonance circuit 250A may be coupled to ground 257A, and resonance circuit 250B may be coupled to ground 257B.

During substrate processing (e.g., during atomic layer deposition, chemical vapor deposition (CVD), and/or the like), an electric field may form around the susceptor (e.g., susceptor 130) and the susceptor substrate support surface (e.g., substrate support surface 135) as electrons travel from the distribution system (e.g., showerhead 180) to the susceptor. As discussed herein, the electric field around different portions of the susceptor or susceptor substrate support surface may differ, causing differing processing results on different portions of the substrate corresponding to the different proximate electric fields. For example, the electric field proximate an outer portion of the substrate and/or susceptor (e.g., outer portion 333 of susceptor 330 in FIG. 3) may differ from the electric field proximate an inner portion of the substrate and/or susceptor (e.g., inner portion 331 of susceptor 330 in FIG. 3). Therefore, in an ALD process, for example, the material deposition on the substrate outer portion (proximate the susceptor outer portion) may be different (e.g., greater than) the material deposition on the substrate inner portion (proximate the susceptor inner portion). To avoid such a difference in substrate processing (e.g., material deposition during ALD), the electric fields proximate different portions of the substrate and/or susceptor may be adjusted.

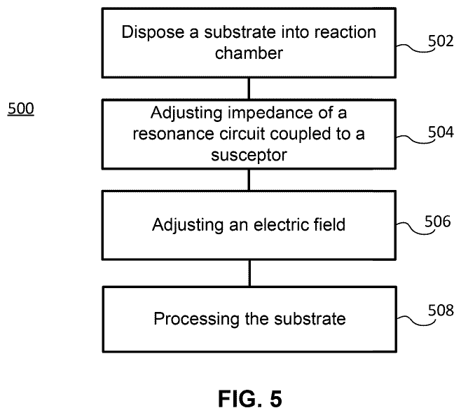

With additional reference to FIG. 5, a method 500 for processing a substrate in a reaction chamber is illustrated, in accordance with various embodiments. It should also be appreciated that the embodiments of the disclosure may be utilized in a reaction chamber configured for a multitude of deposition processes, including but not limited to, ALD, CVD, metalorganic chemical vapor deposition (MOCVD), molecular beam epitaxy (MBE), and physical vapor deposition (PVD). The embodiments of the disclosure may also be utilized in reaction chambers configured for processing a substrate with a reactive precursor, which may also include etch processes, such as, for example, reactive ion etching (RIE), inductively coupled plasma etching (ICP), and electron cyclotron resonance etching (ECR).

In various embodiments, with additional reference to FIGS. 2A, 2B, and 3, a substrate (e.g., substrate 150) may be disposed in a reaction chamber (e.g., reaction chamber 110) (step 502). In various embodiments, substrate 150 may be disposed directly on substrate support surface 135 of susceptor 130. In various embodiments, substrate 150 may be disposed on lift pins 140 protruding from substrate support surface 135 of susceptor 130. In such embodiments, lift pins 140 and/or susceptor 130 may be moved relative to the other such that the top ends of the lift pins are flush with substrate support surface 135 of susceptor 130 or lower than substrate support surface 135 such that substrate 150 is disposed directly on, and in contact with, substrate support surface 135. In various embodiments, lift pins 140 may receive substrate 150, susceptor 130 may be moved upward while lift pins 140 remain stationary, such that lift pins 140 recess into susceptor 130 and pin holes 137, and susceptor 130 receives substrate 150 onto substrate support surface 135 and disposes susceptor 130 in processing position 106 in reaction space 112.

To avoid a difference in the electric fields proximate different portions of the susceptor and substrate, a reactor may comprise one or more tuning circuits. Each tuning circuit may comprise one or more electrodes, which may be coupled to and/or disposed in the susceptor. Each electrode may span proximate a certain portion of the susceptor and/or susceptor substrate support surface, as discussed herein. Each electrode may be coupled to a resonance circuit comprised in the respective tuning circuit, the resonance circuit having an adjustable impedance, allowing the flow of electricity through the respective tuning circuit. Therefore, by adjusting the impedance of a resonance circuit (and thereby the electrode coupled thereto), and the resulting change in electricity flowing through the respective tuning circuit, the electric field proximate the respective electrode may be adjusted. For example, as discussed herein in relation to FIGS. 2A, 2B, and 3, edge electrode 210 may be coupled to and/or disposed in susceptor 130 at an outer portion of susceptor 130 (e.g., outer portion 333 of susceptor 330), and center electrode 220 may be coupled to and/or disposed in susceptor 130 at an inner portion of susceptor 130 (e.g., outer portion 331 of susceptor 330).

In various embodiments, to avoid a difference in substrate processing proximate different portions of the substrate and susceptor, the impedance of a resonance circuit (comprised in a tuning circuit) coupled to an electrode that is coupled to and/or disposed in the susceptor may be adjusted (step 504). Adjusting the impedance of the resonance circuit of a tuning circuit may adjust the electricity flow through the tuning circuit originating from electricity being received in the respective electrode. For example, to adjust the impedance of a resonance circuit, the inductance of an inductor comprised in a resonance circuit may be adjusted, and/or the capacitance of a capacitor comprised in a resonance circuit may be adjusted. As a further example, to adjust the electric field around an outer portion of susceptor 130 (e.g., outer portion 333 of susceptor 330), the capacitance of additional capacitor 256A (which is part of resonance circuit 250A coupled to edge electrode 210, edge electrode 210 spanning at least a portion of the outer portion of susceptor 130 and/or substrate support surface 135) may be adjusted. By so doing, the impedance of resonance circuit 250A and/or edge electrode 210 may be adjusted, thereby changing the electricity flow through tuning circuit 200A. Therefore, the electric field around edge electrode 210 would be adjusted (and the electric field around the outer portion of susceptor 130 and substrate 150) (step 506). Similarly, to adjust the electric field around an inner portion of susceptor 130 (e.g., inner portion 331 of susceptor 330), the capacitance of additional capacitor 256B (which is part of resonance circuit 250B coupled to center electrode 220, center electrode 220 spanning at least a portion of the inner portion of susceptor 130 and/or substrate support surface 135) may be adjusted. By so doing, the impedance of resonance circuit 250B and/or center electrode 220 may be adjusted, thereby changing the electricity flow through tuning circuit 200B. Therefore, the electric field around center electrode 220 would be adjusted (and the electric field around the inner portion of susceptor 130 and substrate 150). With additional reference to FIG. 4, the impedance of the resonance circuits coupled to each of edge electrodes 410A-410D may be adjusted to adjust the electric field proximate edge electrodes 410A-410D (and proximate the outer portion of susceptor 130 and substrate 150), and the impedance of the resonance circuits coupled to each of center electrodes 420A-420D may be adjusted to adjust the electric field proximate center electrodes 420A-420D (and proximate the inner portion of susceptor 130 and substrate 150).

The impedance of the resonance circuits may be adjusted to cause desired electric fields around the different portions of the susceptor and substrate corresponding to the electrode(s) proximate thereto (e.g., to minimize the difference between the electric fields proximate different portions of the susceptor and substrate). For example, the impedance of resonance circuits 250A and 250B may be adjusted to minimize the difference between the electric field around edge electrode 210 (and around the outer portion of susceptor 130 and substrate 150) and the electric field around center electrode 220 (and around the inner portion of susceptor 130 and substrate 150).

In response to, achieving desired electric fields proximate different portions of the susceptor and substrate, the substrate may be processed (step 508).

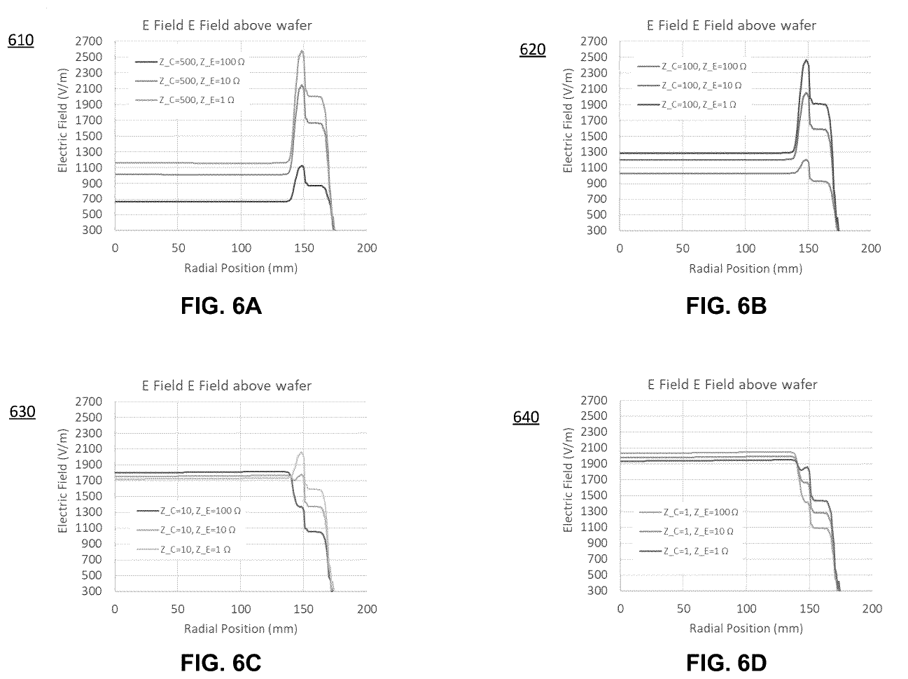

FIGS. 6A-6D display plots of the electric fields above a wafer (i.e. substrate) while varying the impedance proximate the inner portion of a susceptor (proximate a center electrode) and proximate the outer portion of a susceptor (proximate an edge electrode). As displayed in plots 610, 620, 630, and 640, “Z_C” is the impedance (Ω) of the center electrode and respective tuning circuit (an example of tuning circuit 250B and center electrode 220), and “Z_E” is the impedance (Ω) of the edge electrode and respective tuning circuit (an example of tuning circuit 250A and edge electrode 210). As can be seen, the electric field begins to change around the 140 mm radial position of the substrate (caused by the effect from the impedance of the edge electrode), indicating that the inner portion of the substrate is from the 0 mm radial portion to about the 140 mm radial position of the substrate, and the outer portion of the substrate is from the 140 mm radial portion to about the 170 mm radial position of the substrate. In each plot 610, 620, 630, and 640, the impedance of the center electrode is kept constant (500Ω for plot 610, 100Ω for plot 620, 10Ω for plot 630, and 1Ω for plot 640), while the impedance of the edge electrode is varied (varying in three steps of 100, 10, and 1Ω in each plot).

As shown in plots 610, 620, 630, and 640, as the impedance of the center electrode gets lower (from 500Ω in plot 610 to 1Ω in plot 640), there is less of an effect on the electric field between the center electrode and the edge electrode and the outer portion of the substrate. That is, with relatively lower impedance of the center electrode, there is less of a change (or a more predictable change) in the electric field moving from the center electrode to the edge electrode. Therefore, relatively lower center electrode impedance causes the electric field around the edge electrode to be easier (and/or more predictable) to control. Accordingly, the edge profile may be controlled without a significant change of total input power into the resonance circuit coupled to the edge circuit, or into the tuning circuit comprising the edge electrode.

The impedance of an edge electrode may comprise any suitable level, for example, from 0 ohms (Ω) to 10 k Ω. The impedance of a center electrode may comprise any suitable level, for example, from 0 ohms (Ω) to 10 k Ω.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A susceptor assembly for a reactor system, comprising:
a susceptor body defined by a susceptor outer edge, the susceptor body comprising a susceptor outer portion and a susceptor inner portion, wherein the susceptor outer portion is proximate the susceptor outer edge, and the susceptor inner portion is at least partially enclosed within the susceptor outer portion;
a first tuning circuit comprising an edge electrode and a first resonance circuit coupled to the edge electrode, wherein the edge electrode is coupled to the susceptor body; and
a second tuning circuit comprising a center electrode and a second resonance circuit coupled to the center electrode, wherein the center electrode is coupled to the susceptor body;
wherein the first resonance circuit consists of a first node, a second node, a first inductor and a first variable capacitor coupled in series to ground, and a first capacitor coupled in parallel to the first inductor and the first variable capacitor, and
wherein the first variable capacitor connects the first node to the second node, and wherein the first inductor and a first variable capacitor coupled in series connects the first node to the second node.

2. The susceptor assembly of claim 1, wherein the second resonance circuit comprises: a third node, a fourth node, a second inductor, a second variable capacitor coupled in series to ground, and a second capacitor coupled in parallel to the second inductor and the second variable capacitor,
wherein the second variable capacitor connects the first node to the second node, and wherein the second inductor and a second variable capacitor coupled in series connects the third node to the fourth node.

3. The susceptor assembly of claim 1, wherein the second resonance circuit consists of:
a third node, a fourth node, a second inductor, a second variable capacitor coupled in series to ground, and a second capacitor coupled in parallel to the second inductor and the second variable capacitor,
wherein the second variable capacitor connects the first node to the second node, and wherein the second inductor and a second variable capacitor coupled in series connects the third node to the fourth node.

4. The susceptor assembly of claim 2, wherein the first inductor has a first adjustable inductance, and wherein the second inductor has a second adjustable inductance.

5. The susceptor assembly of claim 2, wherein the first capacitor has a first adjustable capacitance, and wherein the second capacitor has a second adjustable capacitance.

6. The susceptor assembly of claim 1, wherein the reactor system further comprises a reaction chamber, and wherein the first resonance circuit is external to the reaction chamber.

7. The susceptor assembly of claim 1, wherein the edge electrode comprises four edge sub-electrodes, and wherein the first resonance circuit is coupled to each of the four edge sub-electrodes.

8. The susceptor assembly of claim 2, wherein the center electrode comprises four sub-electrodes, and wherein the second resonance circuit is coupled to each of the four center sub-electrodes.

9. The susceptor assembly of claim 1, further comprising a substrate support surface on a top surface of the susceptor body, wherein the substrate support surface is configured to hold a substrate, and wherein the edge electrode protrudes further towards the susceptor outer edge than the substrate support surface.

10. A susceptor for a reactor system, comprising:
a susceptor body defined by a susceptor outer edge, the susceptor body comprising a susceptor outer portion and a susceptor inner portion, wherein the susceptor outer portion is proximate the susceptor outer edge, and the susceptor inner portion is within the susceptor outer portion, wherein the substrate support surface is configured to hold a substrate;
an edge electrode coupled to the susceptor body;
a center electrode coupled to the susceptor body;
a first resonance circuit coupled to the edge electrode, wherein the first resonance circuit consists of a first node, a second node, a first inductor and a first variable capacitor coupled in series to ground, and first capacitor coupled in parallel to the first inductor and the first variable capacitor, wherein the first variable capacitor connects the first node to the second node, and
wherein the first inductor and a first variable capacitor coupled in series connects the first node to the second node; and
a second resonance circuit coupled to the center electrode.

11. The susceptor of claim 10, wherein the second resonance circuit comprises:
a third node, a fourth node, a second inductor, a second variable capacitor coupled in series to ground, and a second capacitor coupled in parallel to the second inductor and the second variable capacitor,
wherein the second variable capacitor connects the first node to the second node, and wherein the second inductor and a second variable capacitor coupled in series connects the third node to the fourth node.

12. The susceptor of claim 10, wherein the second resonance circuit consists of:
a third node, a fourth node, a second inductor, a second variable capacitor coupled in series to ground, and a second capacitor coupled in parallel to the second inductor and the second variable capacitor,
wherein the second variable capacitor connects the first node to the second node, and wherein the second inductor and a second variable capacitor coupled in series connects the third node to the fourth node.

13. The susceptor assembly of claim 11, wherein the first inductor has a first adjustable inductance, and wherein the second inductor has a second adjustable inductance.

14. The susceptor assembly of claim 11, wherein the first capacitor has a first adjustable capacitance, and wherein the second capacitor has a second adjustable capacitance.

15. The susceptor of claim 10, wherein the edge electrode spans along at least a portion of the susceptor outer portion, defining at least a portion of an edge electrode shape, wherein the edge electrode at least partially encloses an edge electrode void,
wherein the center electrode is defined by a center electrode outer edge, wherein the center electrode is disposed in the susceptor inner portion and at least partially in the edge electrode void.

16. The susceptor of claim 10, wherein the edge electrode shape comprises a first circular shape, and the center electrode outer edge comprises a second circular shape.

17. A method, comprising:
adjusting an impedance of a first resonance circuit;
adjusting an impedance of a second resonance circuit; and
adjusting a first electric field proximate a first electrode coupled to the first resonance circuit in response to the adjusting the impedance of the first resonance circuit, wherein the first electrode is coupled to a susceptor,
wherein the first resonance circuit consists of a first node, a second node, a first inductor and a first variable capacitor coupled in series to ground, and a first capacitor coupled in parallel to the first inductor and the first variable capacitor, wherein the first variable capacitor connects the first node to the second node, and wherein the first inductor and a first variable capacitor coupled in series connects the first node to the second node.

18. The method of claim 17, further comprising adjusting a second electric field proximate a second electrode coupled to the second resonance circuit in response to the adjusting the impedance of the second resonance circuit, wherein the second electrode is coupled to the susceptor at a different portion than the first electrode.

19. The method of claim 17, wherein the second resonance circuit consists of:
a third node, a fourth node, a second inductor, a second variable capacitor coupled in series to ground, and a second capacitor coupled in parallel to the second inductor and the second variable capacitor,
wherein the second variable capacitor connects the first node to the second node, and wherein the second inductor and a second variable capacitor coupled in series connects the third node to the fourth node.

20. The method of claim 17, wherein the first electrode spans along at least a portion of an outer portion of the susceptor, the outer portion being proximate a susceptor outer edge, and wherein the second electrode is disposed at an inner portion of the susceptor, wherein the inner portion is within the outer portion.
